(19) United States
(12) Patent Application Publication
(10) Pub. No.: US 2026/0165138 A1
(43) Pub. Date: Jun. 11, 2026

(54) PROTECTIVE FILM, METHOD OF FORMING PROTECTIVE FILM, AND SEMICONDUCTOR DEVICE

(71) Applicant: Mitsubishi Electric Corporation, Tokyo (JP)

(72) Inventors: Kosuke KOBASHI, Tokyo (JP); Katsuhisa SAKAI, Tokyo (JP); Naoyoshi SHIRAISHI, Fukuoka (JP); Daisuke CHIKAMORI, Tokyo (JP)

(73) Assignee: Mitsubishi Electric Corporation, Tokyo (JP)

(21) Appl. No.: 19/179,230

(22) Filed: Apr. 15, 2025

(30) Foreign Application Priority Data
Jun. 27, 2024 (JP) 2024-103930

(51) Int. Cl. H10W 42/00

(52) U.S. Cl. CPC H10W 42/121

(57) ABSTRACT

A protective film to protect a surface of a semiconductor wafer includes a first resin film and a second resin film. The semiconductor wafer includes a main surface and a device pattern film provided superficially in the main surface. The first resin film covers the main surface of the semiconductor wafer. The second resin film has a film thickness that is the same as or within 10% greater or smaller than a film thickness of the first resin film. The second resin film includes a protrusion provided on a portion of a surface of the first resin film.

### BACKGROUND

### Technical Field

The present disclosure relates to a protective film to protect a surface of a semiconductor wafer, a method of forming the protective film, and a semiconductor device.

### Description of the Background Art

When a surface protective film is formed over a semiconductor wafer, heating and cooling of the semiconductor wafer leads to shrinkage of the surface protective film, resulting in bowing of the semiconductor wafer as a whole. Japanese Patent 5447296 proposes technology to reduce bowing of a semiconductor wafer by protrusions of protective tape adhered to a surface of the semiconductor wafer.

Bowing of a semiconductor wafer in a process of manufacturing a semiconductor device causes a transfer error, breakage of the semiconductor wafer, and the like. In a manufacturing method disclosed in Japanese Patent 5447296, when the surface of the semiconductor wafer is mounted to a stage, the protective tape adhered to the surface of the semiconductor wafer enters grooves of the stage. Portions of the protective tape corresponding to the grooves of the stage are thereby deformed to form the protrusions. With this method, however, protrusions of sufficient sizes are less likely to be formed, and it is difficult to perform flexible operation, for example, because a new stage is required to be prepared each time a layout of the protrusions is changed. Technology to more effectively reduce bowing of the semiconductor wafer is required.

### SUMMARY

It is an object of the present disclosure to provide technology to reduce bowing of a semiconductor wafer.

A protective film according to the present disclosure is a protective film to protect a surface of a semiconductor wafer and includes a first resin film and a second resin film. The semiconductor wafer includes a main surface and a device pattern film provided superficially in the main surface. The first resin film covers the main surface of the semiconductor wafer. The second resin film has a film thickness that is the same as or within 10% greater or smaller than a film thickness of the first resin film. The second resin film includes a protrusion provided on a portion of a surface of the first resin film.

Technology to reduce bowing of the semiconductor wafer is provided.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of a protective film according to Embodiment 1;

FIG. 2 is a cross-sectional view illustrating a configuration of a semiconductor wafer and a first resin film;

FIG. 3 is a cross-sectional view illustrating a configuration of a protective film according to Embodiment 2;

FIGS. 4A to 4D are diagrams showing examples of a layout of protrusions;

FIG. 5 is a plan view illustrating a configuration of a semiconductor wafer according to Embodiment 4;

FIG. 6 is a plan view illustrating a configuration of a single device pattern formation portion;

FIG. 7 is a cross-sectional view illustrating a configuration of the single device pattern formation portion;

FIG. 8 is a cross-sectional view illustrating a configuration of a protective film according to Embodiment 5;

FIG. 9 is a diagram schematically showing a manufacturing method of applying a resin onto a semiconductor wafer by dispensing;

FIG. 10 is a flowchart showing a method of manufacturing a protective film according to Embodiment 7;

FIGS. 11A to 11C are cross-sectional views illustrating configurations of a protective film in respective steps;

FIG. 12 is a flowchart showing another method of manufacturing the protective film according to Embodiment 7;

FIGS. 13A to 13C are cross-sectional views illustrating processing during grinding of a back surface in a subsequent step;

FIG. 14 is a flowchart showing a method of manufacturing a protective film according to Embodiment 8;

FIGS. 15A and 15B are cross-sectional views illustrating configurations of a protective film in respective steps;

FIG. 16 is a flowchart showing a method of manufacturing a protective film according to Embodiment 9;

FIGS. 17A to 17C are cross-sectional views illustrating configurations of a protective film in respective steps;

FIG. 18 is a flowchart showing a method of manufacturing a protective film according to Embodiment 10; and

FIGS. 19A and 19B are cross-sectional views illustrating configurations of a protective film in respective steps.

### DESCRIPTION OF THE PREFERRED EMBODIMENTS

### Embodiment 1

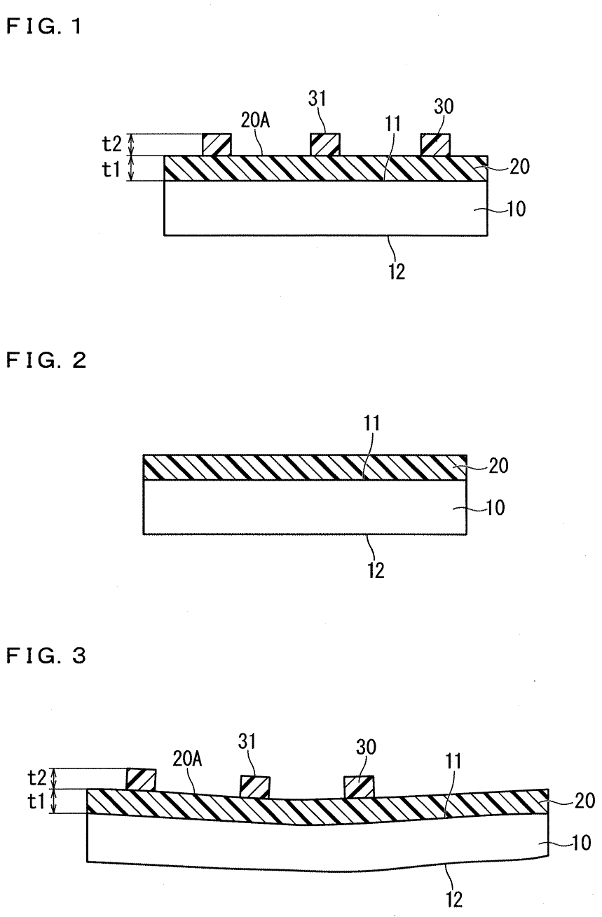

FIG. 1 is a cross-sectional view illustrating a configuration of a protective film according to Embodiment 1. The protective film is a protective film to protect a surface of a semiconductor wafer 10 and includes a first resin film 20 and a second resin film 30. FIG. 2 is a cross-sectional view illustrating a configuration of the semiconductor wafer 10 and the first resin film 20.

The semiconductor wafer 10 includes a first main surface 11, a second main surface 12, and a device pattern film (not illustrated). The second main surface 12 is a surface opposite the first main surface 11. For example, the first main surface 11 is a front surface of the semiconductor wafer 10, and the second main surface 12 is a back surface of the semiconductor wafer 10. The semiconductor wafer 10 is formed of one or more types of materials selected from the group consisting of silicon, silicon carbide, and gallium nitride, for example.

The device pattern film is provided superficially in the first main surface 11. A semiconductor element structure (not illustrated), such as a transistor, has been formed in the device pattern film.

The first resin film 20 is provided to cover the entire first main surface 11 of the semiconductor wafer 10. The first resin film 20 has a function to protect the device pattern film in a subsequent step in a process of manufacturing a semiconductor device.

The second resin film 30 includes protrusions 31 provided on portions of a surface 20A of the first resin film 20. The protrusions 31 protrude beyond the surface 20A of the first resin film 20. In Embodiment 1, the protrusions 31 are provided at any positions. In Embodiment 1, the plurality of protrusions 31 are provided, and neighboring protrusions 31 are separated by any distance. A film thickness t2 of the second resin film 30 is similar to a film thickness t1 of the first resin film 20, and, as a specific range thereof, the film thickness t2 of the second resin film 30 is the same as or within 10% greater or smaller than the film thickness t1 of the first resin film 20. The second resin film 30 is formed of the same material as the first resin film 20, for example.

In a subsequent step in the process of manufacturing the semiconductor device, the semiconductor wafer 10 is subjected to a substantial degree of heating. When the protrusions 31 of the second resin film 30 are not provided, the first resin film 20 shrinks during cooling after heating to cause downward bowing of the semiconductor wafer 10. As a result, a transfer error or breakage of the semiconductor wafer 10 occurs in a subsequent step.

In the semiconductor device according to Embodiment 1, the second resin film 30 includes the protrusions 31. The protrusions 31 of the second resin film 30 expand in a direction of the surface of the semiconductor wafer 10 during cooling after heating to absorb shrinkage of the first resin film 20. Bowing of the semiconductor wafer 10 is reduced compared with a structure in which the second resin film 30 is not provided. As a result, the transfer error and breakage of the semiconductor wafer 10 in the subsequent step are prevented to improve yield in the manufacturing process.

The film thickness t2 of the second resin film 30 is preferably similar to the film thickness t1 of the first resin film 20. A great film thickness t2 of the protrusions 31 of the second resin film 30 has a great effect of correcting bowing of the semiconductor wafer 10. It, however, causes trouble, such as poor adhesion of the semiconductor wafer 10, due to contact of the protrusions 31 with a transfer arm, a processing stage, and the like in the subsequent step. On the other hand, a small film thickness t2 of the protrusions 31 of the second resin film 30 has a small effect of correcting bowing of the semiconductor wafer 10. It is effective to form thick protrusions 31 to the extent that the subsequent step is not affected.

In summary, the protective film according to Embodiment 1 is the protective film to protect the surface of the semiconductor wafer 10 and includes the first resin film 20 and the second resin film 30. The semiconductor wafer 10 includes the first main surface 11 and the device pattern film provided superficially in the first main surface 11. The first resin film 20 covers the first main surface 11 of the semiconductor wafer 10. The second resin film 30 has the film thickness that is the same as or within 10% greater or smaller than the film thickness of the first resin film 20. The second resin film 30 includes the protrusions 31 provided on the portions of the surface 20A of the first resin film 20.

According to such a semiconductor device, bowing of the semiconductor wafer 10 in the manufacturing process is reduced. Furthermore, a layout of the protrusions 31 can flexibly be changed, so that bowing of the semiconductor wafer 10 is easily controlled.

### Embodiment 2

In Embodiment 2, a difference from Embodiment 1 will be described. FIG. 3 is a cross-sectional view illustrating a configuration of a protective film according to Embodiment 2.

The semiconductor wafer 10 has a crystal orientation based on arrangement of atoms constituting the semiconductor wafer 10. The semiconductor wafer 10 according to Embodiment 2 bows downward so that the first main surface 11 is concave in accordance with a crystal plane orientation of the first main surface 11. That is to say, the semiconductor wafer 10 bows downward in a U shape. When the semiconductor wafer 10 bows, bowing is likely to occur in a particular direction based on the crystal orientation. A silicon wafer having a (100) plane is likely to bow in a direction along two cleavage planes orthogonal to a main surface of the silicon wafer. The cleavage planes are (111) planes.

The protrusions 31 of the second resin film 30 according to Embodiment 2 are provided on the first resin film 20 along a direction of bowing of the semiconductor wafer 10. That is to say, the protrusions 31 of the second resin film 30 are provided along a direction of extension of a bottom of the U shape. For example, the plurality of protrusions 31 extend in a direction parallel to the direction of extension of the bottom of the U shape. The film thickness t2 of the second resin film 30 is similar to the film thickness t1 of the first resin film 20, and, as a specific range thereof, the film thickness t2 of the second resin film 30 is the same as or within 10% greater or smaller than the film thickness t1 of the first resin film 20.

According to such a configuration, a greater effect of reducing bowing than that obtained for the semiconductor device according to Embodiment 1 can be obtained. The transfer error and breakage of the semiconductor wafer 10 in the subsequent step are prevented to improve yield in the manufacturing process.

Bowing of the semiconductor wafer 10 is not only due to the crystal plane orientation but also due to the device pattern film provided in the first main surface 11 of the semiconductor wafer 10. Depending on a configuration of the device pattern film, the device pattern film has a greater influence on the direction of bowing than the crystal plane orientation of the semiconductor wafer 10. In particular, when the device pattern film has a plurality of trenches along one direction parallel to the first main surface 11 of the semiconductor wafer 10, bowing of the semiconductor wafer 10 due to the device pattern film appears prominently.

In Embodiment 2, when the semiconductor wafer 10 bows downward in the U shape in accordance with the device pattern film, the protrusions 31 of the second resin film 30 are provided along the direction of extension of the bottom of the U shape as in a case of bowing due to the crystal plane orientation.

According to such a configuration, a greater effect of reducing bowing than that obtained for the semiconductor device according to Embodiment 1 can be obtained. The transfer error and breakage of the semiconductor wafer 10 in the subsequent step are prevented to improve yield in the manufacturing process.

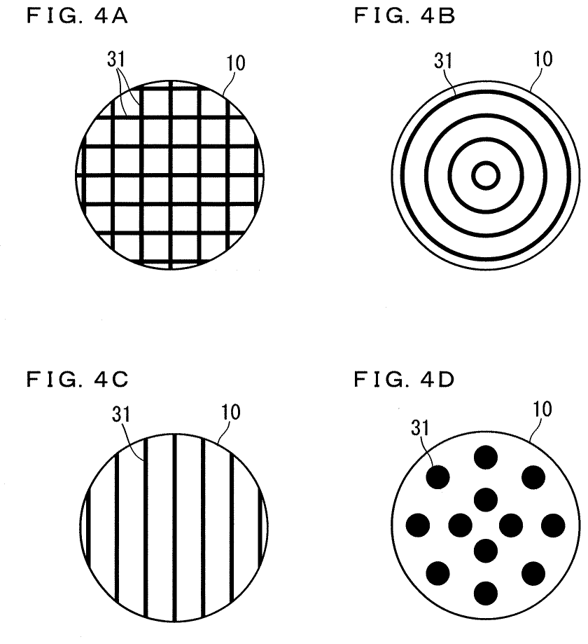

The layout of the protrusions 31 is not limited to the above-mentioned layout. FIGS. 4A to 4D are diagrams showing examples of the layout of the protrusions 31. The protrusions 31 may be provided in the form of a grid (FIG. 4A), concentric circles (FIG. 4B), stripes (FIG. 4C), or dots (FIG. 4D). A layout having a greater effect of reducing bowing is applied in accordance with the crystal plane orientation, a diameter, a thickness, and the like of the semiconductor wafer 10. Alternatively, a layout having a greater effect of reducing bowing is applied in accordance with the configuration of the device pattern film.

### Embodiment 3

In Embodiment 3, a difference from Embodiment 1 or 2 will be described. The semiconductor wafer 10, the device pattern film, and the first resin film 20 have the same configuration as that in Embodiment 1.

The second resin film 30 is formed of a different resin from the first resin film 20. For example, the second resin film 30 is formed of a thermally expandable resin.

The protrusions 31 of the second resin film 30 formed of the thermally expandable resin expand mainly in the direction of the surface of the semiconductor wafer 10 during cooling after heating. This expansion appears more prominently than expansion of the second resin film 30 according to Embodiment 1 in the direction of the surface of the semiconductor wafer 10. The protrusions 31 of the second resin film 30 more greatly absorb shrinkage of the first resin film 20, so that a greater effect of reducing bowing can be obtained. As a result, the transfer error and breakage of the semiconductor wafer 10 in the subsequent step are prevented to improve yield in the manufacturing process.

### Embodiment 4

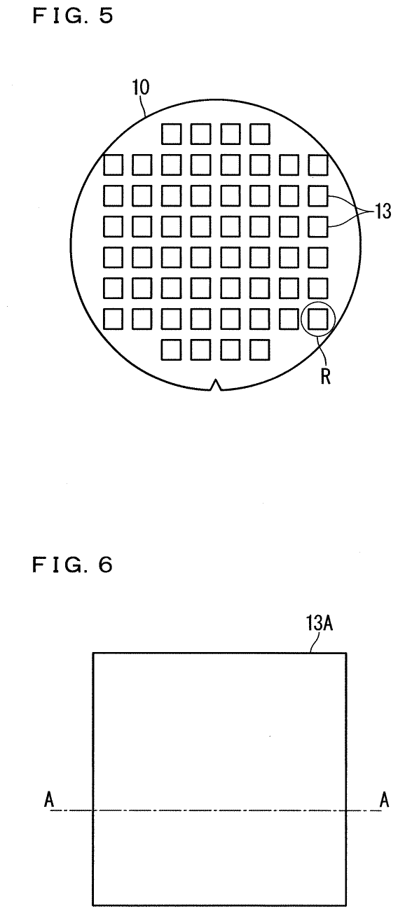

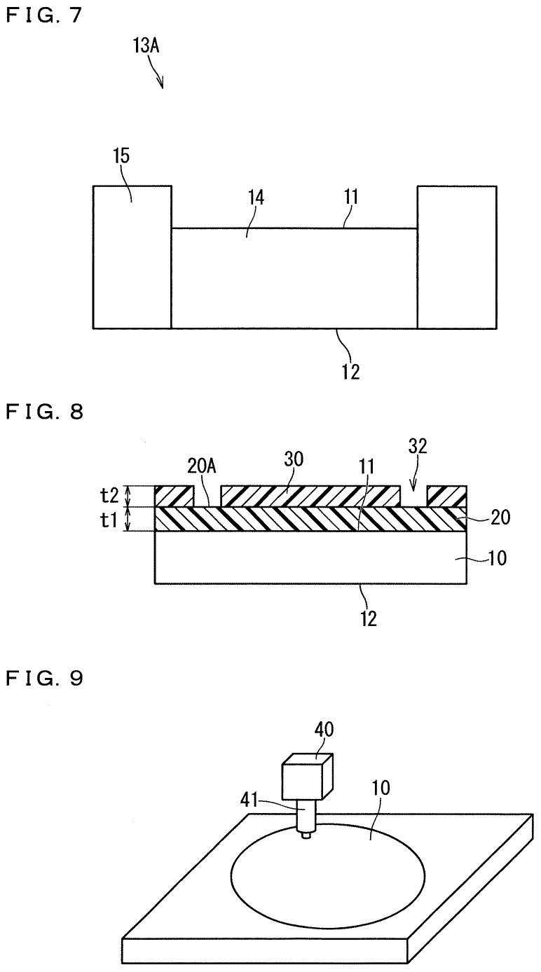

FIG. 5 is a plan view illustrating a configuration of a semiconductor wafer 10 according to Embodiment 4. A plurality of semiconductor chips, that is, a plurality of device pattern formation portions 13 are provided in the semiconductor wafer 10. FIG. 6 is a plan view illustrating a configuration of a single device pattern formation portion 13A. FIG. 6 corresponds to an enlarged view of a region R shown in FIG. 5. FIG. 7 is a cross-sectional view illustrating a configuration of the single device pattern formation portion 13A. FIG. 7 corresponds to a cross-sectional view taken along the line A-A shown in FIG. 6.

The semiconductor wafer 10 includes the first main surface 11, the second main surface 12, and the device pattern film (not illustrated). The second main surface 12 is the surface opposite the first main surface 11. The semiconductor wafer 10 is formed of one or more types of materials selected from the group consisting of silicon, silicon carbide, and gallium nitride, for example.

The device pattern film is provided superficially in the first main surface 11. The semiconductor element structure, such as the transistor, has been formed in the device pattern film.

From among the plurality of device pattern formation portions 13 provided in the semiconductor wafer 10, a single device pattern formation portion 13A corresponds to a single semiconductor chip. The device pattern film for the single device pattern formation portion 13A includes a conducting portion 14 and a termination portion 15. The termination portion 15 is disposed around the conducting portion 14. The semiconductor wafer 10 has a greater thickness in the termination portion 15 than in the conducting portion 14.

There is a trade-off between a breakdown voltage and an on resistance of the semiconductor device and a thickness of the semiconductor wafer 10. With increasing thickness of the semiconductor wafer 10, the breakdown voltage increases, while the on resistance increases.

As illustrated in FIG. 7, in Embodiment 4, only the termination portion 15 provided to secure the breakdown voltage without directly contributing to conduction has a great thickness. Breakdown voltage performance of the semiconductor device is thus improved. Only the conducting portion 14 directly contributing to conduction has a small thickness. The on resistance of the semiconductor device is thus reduced to improve conduction performance. The thickness of the semiconductor wafer 10 has the above-mentioned configuration, so that desired electrical characteristics can be obtained.

When the termination portion 15 has a great thickness, the breakdown voltage performance is improved, while the number of process changes in an assembly and the like in the subsequent step increases. It is effective to provide a thick termination portion 15 to the extent that the influence on the subsequent step is taken into account.

### Embodiment 5

FIG. 8 is a cross-sectional view illustrating a configuration of a protective film according to Embodiment 5. The semiconductor wafer 10, the device pattern film (not illustrated), and the first resin film 20 have the same configuration as that in Embodiment 1.

The second resin film 30 includes recesses 32 from which portions of the surface 20A of the first resin film 20 are exposed. In Embodiment 5, the recesses 32 are provided at any positions. The film thickness t2 of the second resin film 30 is similar to the film thickness t1 of the first resin film 20, and, as a specific range thereof, the film thickness t2 of the second resin film 30 is the same as or within 10% greater or smaller than the film thickness t1 of the first resin film 20. The second resin film 30 is formed of the same material as the first resin film 20.

The second resin film 30 includes the recesses 32, so that the first resin film 20 and the second resin film 30 shrink not continuously but intermittently during cooling after heating performed in the subsequent step. Shrinking portions are dispersed, and a degree of shrinkage of the first resin film 20 and the second resin film 30 as a whole is reduced. Bowing of the semiconductor wafer 10 is thus reduced. As a result, the transfer error and breakage of the semiconductor wafer 10 in the subsequent step are prevented to improve yield in the manufacturing process.

### Embodiment 6

In Embodiment 6, a difference from Embodiment 5 will be described. The semiconductor wafer 10 bows downward so that the first main surface 11 is concave in accordance with the crystal plane orientation of the first main surface 11 as in Embodiment 2. That is to say, the semiconductor wafer 10 bows downward in the U shape.

The recesses 32 of the second resin film 30 according to Embodiment 6 are provided along the direction of bowing of the semiconductor wafer 10 (not illustrated). That is to say, the recesses 32 of the second resin film 30 are provided along the direction of extension of the bottom of the U shape. For example, the plurality of recesses 32 extend in the direction parallel to the direction of extension of the bottom of the U shape.

According to such a configuration, a greater effect of reducing bowing than that obtained for the semiconductor device according to Embodiment 5 can be obtained. The transfer error and breakage of the semiconductor wafer 10 in the subsequent step are prevented to improve yield in the manufacturing process.

As in Embodiment 2, bowing of the semiconductor wafer 10 is also due to the device pattern film provided superficially in the first main surface 11. Depending on the configuration of the device pattern film, the device pattern film has a greater influence on the direction of bowing than the crystal plane orientation of the semiconductor wafer 10.

In Embodiment 6, when the semiconductor wafer 10 bows downward in the U shape in accordance with the device pattern film, the recesses 32 of the second resin film 30 are provided along the direction of extension of the bottom of the U shape as in a case of bowing due to the crystal plane orientation.

According to such a configuration, a greater effect of reducing bowing than that obtained for the semiconductor device according to Embodiment 5 can be obtained. The transfer error and breakage of the semiconductor wafer 10 in the subsequent step are prevented to improve yield in the manufacturing process.

The layout of the recesses 32 is not limited to the above-mentioned layout. The recesses 32 may be provided in the form of concentric circles, a grid, stripes, or dots as with the protrusions 31 in Embodiment 2, for example. A layout having a greater effect of reducing bowing is applied in accordance with the crystal plane orientation, the diameter, the thickness, and the like of the semiconductor wafer 10. Alternatively, a layout having a greater effect of reducing bowing is applied in accordance with the configuration of the device pattern film.

### Embodiment 7

In Embodiment 7, a method of manufacturing the protective film according to any one of Embodiments 1 to 4 will be described.

FIG. 9 is a diagram schematically showing a manufacturing method of applying a resin onto the semiconductor wafer 10 by dispensing. In dispensing, a dispensing mechanism 40 extrudes a certain quantity of a resin loaded into a syringe 41 at gas pressure and the like to apply the resin onto the semiconductor wafer 10 as a target of application. The dispensing mechanism 40 properly controls pressure, such as the gas pressure, so that a resin film having various thicknesses is partially formed.

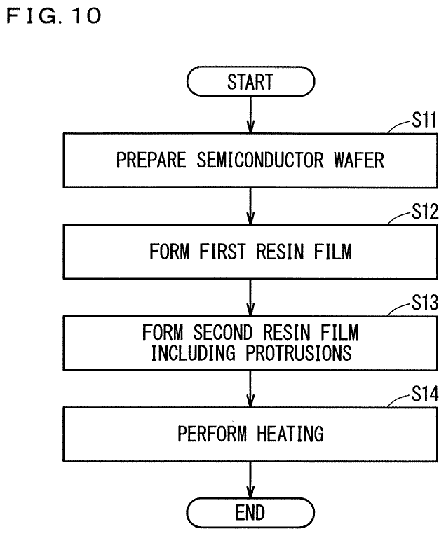

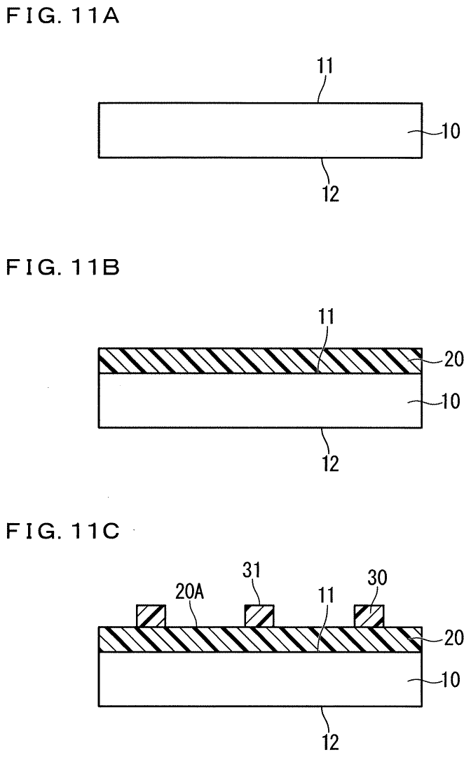

FIG. 10 is a flowchart showing the method of manufacturing the protective film according to Embodiment 7. FIGS. 11A to 11C are cross-sectional views illustrating configurations of the protective film in respective steps.

In step S11, the semiconductor wafer 10 is prepared. FIG. 11A illustrates a configuration of the semiconductor wafer 10. The semiconductor wafer 10 includes the first main surface 11, the second main surface 12, and the device pattern film. The second main surface 12 is the surface opposite the first main surface 11. The semiconductor wafer 10 is formed of one or more types of materials selected from the group consisting of silicon, silicon carbide, and gallium nitride, for example. The device pattern film is provided superficially in the first main surface 11. The semiconductor element structure, such as the transistor, has been formed in the device pattern film.

In step S12, the first resin film 20 is formed to cover the first main surface 11 of the semiconductor wafer 10 including the device pattern film. FIG. 11B illustrates a configuration of the semiconductor wafer 10 over which the first resin film 20 has been formed. The first resin film 20 is formed by dispensing. A resin is applied onto the first main surface 11 of the semiconductor wafer 10 with the syringe 41 using the gas pressure to form the first resin film 20.

In step S13, the second resin film 30 including the protrusions 31 provided on the portions of the surface 20A of the first resin film 20 is formed. FIG. 11C illustrates a configuration of the semiconductor wafer 10 over which the second resin film 30 has been formed. The second resin film 30 is formed by dispensing. A resin is applied onto portions of the first resin film 20 with the syringe 41 using the gas pressure. The resin is applied only at positions where the protrusions 31 are formed, for example. The protrusions 31 of the second resin film 30 are thereby formed. The film thickness t2 of the second resin film 30 is similar to the film thickness t1 of the first resin film 20, and, as a specific range thereof, the film thickness t2 of the second resin film 30 is the same as or within 10% greater or smaller than the film thickness t1 of the first resin film 20.

In step S14, the semiconductor wafer 10 over which the first resin film 20 and the second resin film 30 have been formed is subjected to heating. After heating, the semiconductor wafer 10 is cooled to a room temperature. A cooling method is natural cooling, for example, and may be any other cooling means.

After steps S11 to S14, the subsequent step is performed. The method of manufacturing the semiconductor device according to Embodiment 7 is as described above.

A semiconductor device manufactured by the manufacturing method according to Embodiment 7 prevents the transfer error and breakage of the semiconductor wafer 10 in the subsequent step to improve yield.

When the protective film according to Embodiment 2 is manufactured, the protrusions 31 of the second resin film 30 are formed along the U-shaped downward bowing due to the crystal plane orientation or the U-shaped downward bowing due to the device pattern film. A greater effect of reducing bowing is thereby obtained.

When the protective film according to Embodiment 3 is manufactured, the thermally expandable resin is applied as the second resin film 30. A greater effect of reducing bowing is thereby obtained.

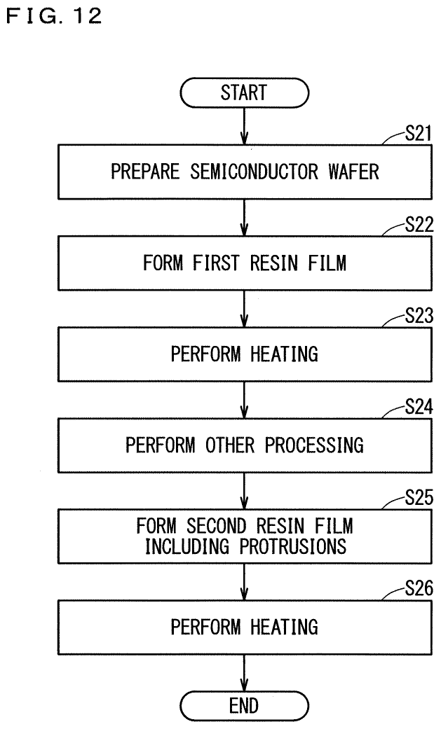

The step of forming the second resin film 30 as step S13 is not required to be performed continuously after the step of forming the first resin film 20 as step S12. FIG. 12 is a flowchart showing another method of manufacturing the protective film according to Embodiment 7. The step of preparing the semiconductor wafer as step S21 and the step of forming the first resin film 20 as step S22 are respectively the same as step S11 and step S12 shown in FIG. 10.

In step S23, heating and cooling are performed. In step S24, the other processing is performed. In step S25, the second resin film 30 is formed. For example, the resin is applied only at the positions where the protrusions 31 are formed on the first resin film 20, for example. In step S26, heating and cooling are performed.

When an abnormality occurs in the subsequent step due to the protrusions 31 of the second resin film 30, the abnormality is avoided by changing a timing of forming the second resin film 30.

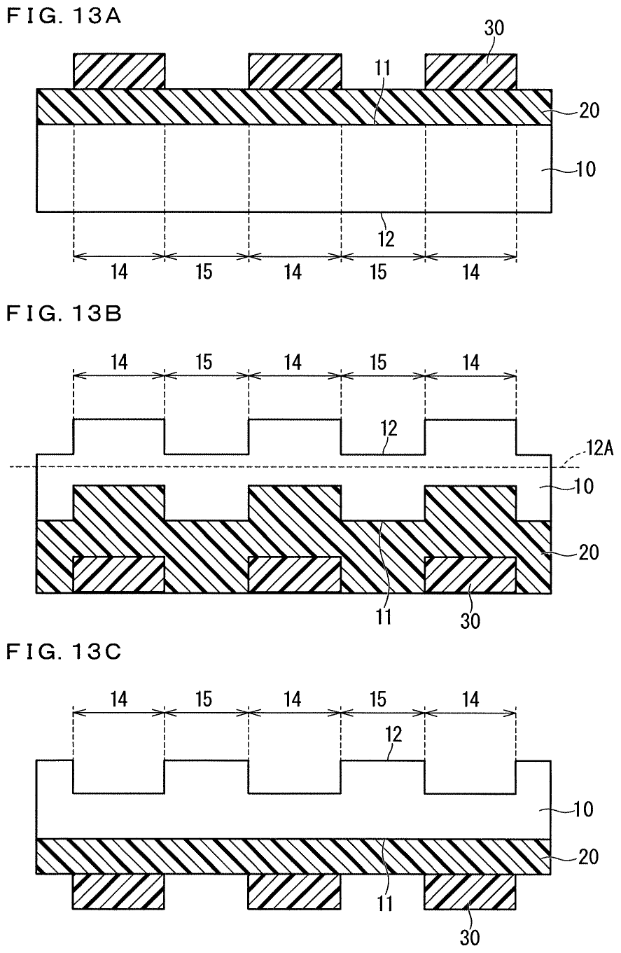

When there is a region where the semiconductor wafer 10 should have a smaller thickness as the conducting portion 14 according to Embodiment 4, the protrusions 31 of the second resin film 30 are formed in the region. The semiconductor device in which the semiconductor wafer 10 has a greater thickness in the termination portion 15 than in the conducting portion 14 is manufactured during grinding of the back surface in the subsequent step. FIGS. 13A to 13C are cross-sectional views illustrating processing during grinding of the back surface in the subsequent step. FIG. 13A illustrates a configuration of the semiconductor wafer 10 over which the second resin film 30 has been formed. The semiconductor wafer 10 is inverted so that the first main surface 11 over which the first resin film 20 and the second resin film 30 have been formed is suctioned to a grinding stage (not illustrated). This suction allows for adjustment to remove steps between the first resin film 20 and the second resin film 30, and irregularities along the steps formed at the first main surface 11 are formed at the second main surface 12 of the semiconductor wafer 10. FIG. 13B illustrates a configuration of the semiconductor wafer 10 in which the second main surface 12 has the irregularities. The second main surface 12 is ground in this state so that the semiconductor wafer 10 has a thickness to a height 12A. Suction to the grinding stage is then released, so that the semiconductor device in which a portion where the second resin film 30 is formed has the thickness in the conducting portion 14 and a portion where the second resin film 30 is not formed has the thickness in the termination portion 15 is manufactured. That is to say, the semiconductor device in which the semiconductor wafer 10 has a greater thickness in the termination portion 15 than in the conducting portion 14 is manufactured. FIG. 13C illustrates a configuration of the semiconductor wafer 10 formed to have a greater thickness in the termination portion 15 than in the conducting portion 14. Such a semiconductor device has improved breakdown voltage performance and conduction performance.

### Embodiment 8

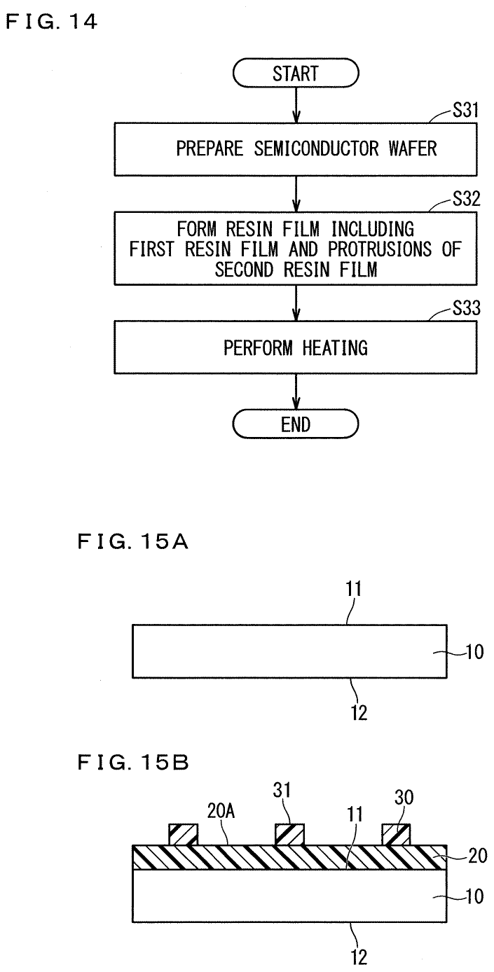

In Embodiment 8, a method of manufacturing the protective film according to any one of Embodiments 1 to 3 will be described. FIG. 14 is a flowchart showing the method of manufacturing the protective film according to Embodiment 8. FIGS. 15A and 15B are cross-sectional views illustrating configurations of the protective film in respective steps.

In step S31, the semiconductor wafer 10 is prepared. FIG. 15A illustrates a configuration of the semiconductor wafer 10. The semiconductor wafer 10 includes the first main surface 11, the second main surface 12, and the device pattern film. The second main surface 12 is the surface opposite the first main surface 11. The semiconductor wafer 10 is formed of one or more types of materials selected from the group consisting of silicon, silicon carbide, and gallium nitride, for example. The device pattern film is provided superficially in the first main surface 11. The semiconductor element structure, such as the transistor, has been formed in the device pattern film.

In step S32, a resin film including the first resin film 20 and the protrusions 31 of the second resin film 30 is formed. FIG. 15B illustrates a configuration of the semiconductor wafer 10 over which the first resin film 20 and the protrusions 31 of the second resin film 30 have been formed. The resin film is formed by dispensing. A resin is applied onto the first main surface 11 of the semiconductor wafer 10 with the syringe 41 using first gas pressure to form the first resin film 20. The dispensing mechanism 40 performs control so that the pressure, such as the gas pressure, increases only at a timing of applying the protrusions 31. A resin is herein applied onto portions of the first main surface 11 with the syringe 41 using second gas pressure higher than the first gas pressure when the first resin film 20 is formed. The first resin film 20 and the protrusions 31 of the second resin film 30 are thereby formed in one go. The film thickness t2 of the second resin film 30 is similar to the film thickness t1 of the first resin film 20, and, as a specific range thereof, the film thickness t2 of the second resin film 30 is the same as or within 10% greater or smaller than the film thickness t1 of the first resin film 20.

In step S33, the semiconductor wafer 10 over which the first resin film 20 and the second resin film 30 have been formed is subjected to heating. After heating, the semiconductor wafer 10 is cooled to the room temperature. The cooling method is natural cooling, for example, and may be any other cooling means.

After steps S31 to S33, the subsequent step is performed. The method of manufacturing the semiconductor device according to Embodiment 8 is as described above.

A semiconductor device manufactured by the manufacturing method according to Embodiment 8 prevents the transfer error and breakage of the semiconductor wafer 10 in the subsequent step to improve yield. Furthermore, a processing time is reduced in the manufacturing method according to Embodiment 8 compared with that according to Embodiment 7 as the first resin film 20 and the protrusions 31 of the second resin film 30 are formed in one go.

When the semiconductor device according to Embodiment 2 is manufactured, the protrusions 31 of the second resin film 30 are formed along the U-shaped downward bowing due to the crystal plane orientation or the U-shaped downward bowing due to the device pattern film. A greater effect of reducing bowing is thereby obtained.

When there is the region where the semiconductor wafer 10 should have a smaller thickness as the conducting portion 14 according to Embodiment 4, the protrusions 31 of the second resin film 30 are formed in the region. The semiconductor device in which the semiconductor wafer 10 has a greater thickness in the termination portion 15 than in the conducting portion 14 is manufactured during grinding of the back surface in the subsequent step. The semiconductor wafer 10 is inverted so that the first main surface 11 over which the first resin film 20 and the second resin film 30 have been formed is suctioned to the grinding stage (not illustrated). This suction allows for adjustment to remove the steps between the first resin film 20 and the second resin film 30, and the irregularities along the steps formed at the first main surface 11 are formed at the second main surface 12 of the semiconductor wafer 10 (FIG. 13B). The second main surface 12 is ground in this state so that the semiconductor wafer 10 has the thickness to the height 12A. Suction to the grinding stage is then released, so that the semiconductor device in which the portion where the second resin film 30 is formed has the thickness in the conducting portion 14 and the portion where the second resin film 30 is not formed has the thickness in the termination portion 15 is manufactured (FIG. 13C). That is to say, the semiconductor device in which the semiconductor wafer 10 has a greater thickness in the termination portion 15 than in the conducting portion 14 is manufactured. Such a semiconductor device has improved breakdown voltage performance and conduction performance.

### Embodiment 9

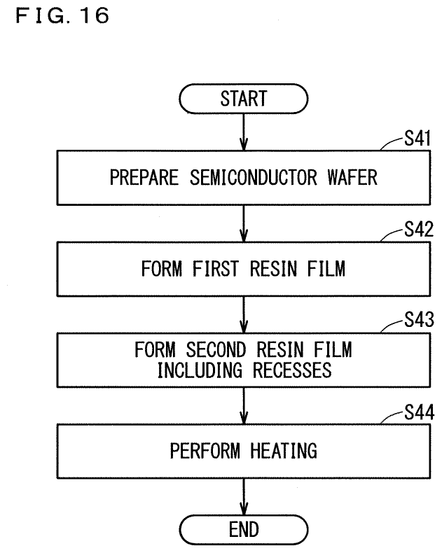

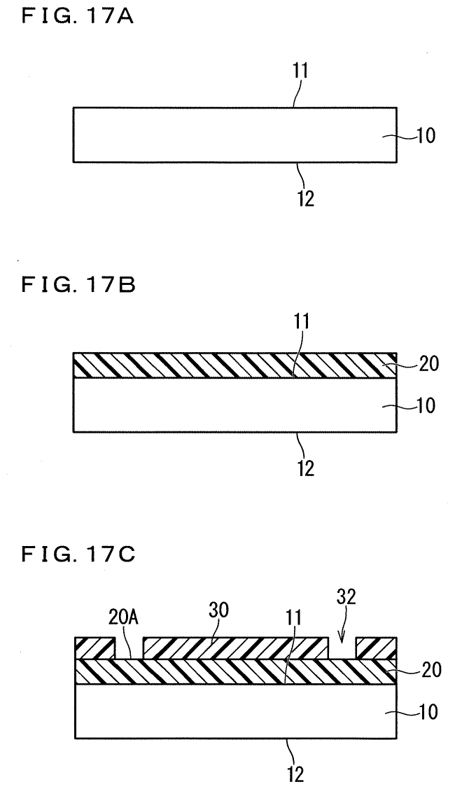

In Embodiment 9, a method of manufacturing the protective film according to Embodiment 5 or 6 will be described. FIG. 16 is a flowchart showing the method of manufacturing the protective film according to Embodiment 9. FIGS. 17A to 17C are cross-sectional views illustrating configurations of the protective film in respective steps.

In step S41, the semiconductor wafer 10 is prepared. FIG. 17A illustrates a configuration of the semiconductor wafer 10. The semiconductor wafer 10 includes the first main surface 11, the second main surface 12, and the device pattern film. The second main surface 12 is the surface opposite the first main surface 11. The semiconductor wafer 10 is formed of one or more types of materials selected from the group consisting of silicon, silicon carbide, and gallium nitride, for example. The device pattern film is provided superficially in the first main surface 11. The semiconductor element structure, such as the transistor, has been formed in the device pattern film.

In step S42, the first resin film 20 is formed to cover the first main surface 11 of the semiconductor wafer 10 including the device pattern film. FIG. 17B illustrates a configuration of the semiconductor wafer 10 over which the first resin film 20 has been formed. The first resin film 20 is formed by dispensing. A resin is applied onto the first main surface 11 of the semiconductor wafer 10 with the syringe 41 using the gas pressure to form the first resin film 20.

In step S43, the second resin film 30 including the recesses 32 provided at the portions of the surface 20A of the first resin film 20 is formed. FIG. 17C illustrates a configuration of the semiconductor wafer 10 over which the second resin film 30 has been formed. The second resin film 30 is formed by dispensing. A resin is applied onto portions of the first resin film 20 with the syringe 41 using the gas pressure. The resin is not applied only at positions where the recesses 32 are formed, for example. The recesses 32 of the second resin film 30 are thereby formed. The film thickness t2 of the second resin film 30 is similar to the film thickness t1 of the first resin film 20, and, as a specific range thereof, the film thickness t2 of the second resin film 30 is the same as or within 10% greater or smaller than the film thickness t1 of the first resin film 20.

In step S44, the semiconductor wafer 10 over which the first resin film 20 and the second resin film 30 have been formed is subjected to heating. After heating, the semiconductor wafer 10 is cooled to the room temperature. The cooling method is natural cooling, for example, and may be any other cooling means.

After steps S41 to S44, the subsequent step is performed. The method of manufacturing the semiconductor device according to Embodiment 9 is as described above.

A semiconductor device manufactured by the manufacturing method according to Embodiment 9 prevents the transfer error and breakage of the semiconductor wafer 10 in the subsequent step to improve yield.

When the semiconductor device according to Embodiment 6 is manufactured, the recesses 32 of the second resin film 30 are formed along the U-shaped downward bowing due to the crystal plane orientation or the U-shaped downward bowing due to the device pattern film. A greater effect of reducing bowing is thereby obtained.

### Embodiment 10

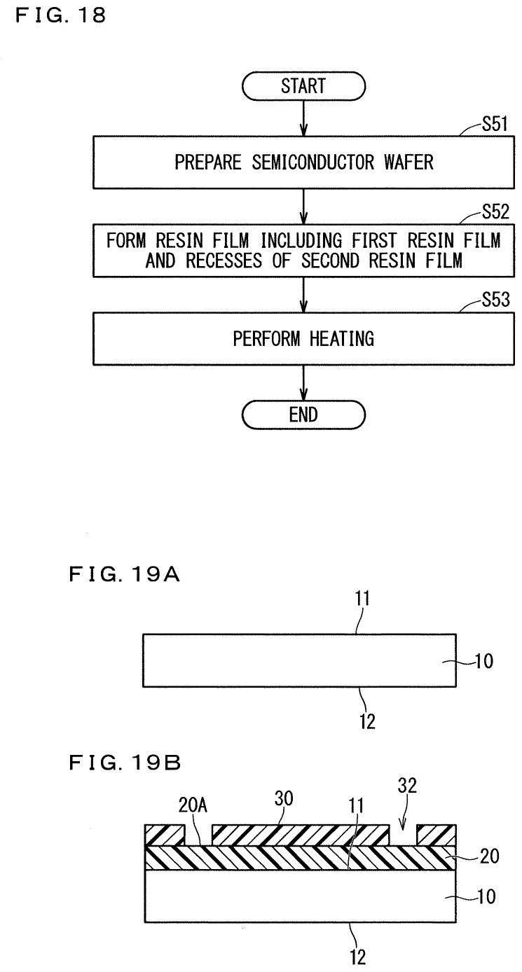

In Embodiment 10, a method of manufacturing the protective film according to Embodiment 5 or 6 will be described. FIG. 18 is a flowchart showing the method of manufacturing the protective film according to Embodiment 10. FIGS. 19A and 19B are cross-sectional views illustrating configurations of the protective film in respective steps.

In step S51, the semiconductor wafer 10 is prepared. FIG. 19A illustrates a configuration of the semiconductor wafer 10. The semiconductor wafer 10 includes the first main surface 11, the second main surface 12, and the device pattern film. The second main surface 12 is the surface opposite the first main surface 11. The semiconductor wafer 10 is formed of one or more types of materials selected from the group consisting of silicon, silicon carbide, and gallium nitride, for example. The device pattern film is provided superficially in the first main surface 11. The semiconductor element structure, such as the transistor, has been formed in the device pattern film.

In step S52, a resin film including the first resin film 20 and the recesses 32 of the second resin film 30 is formed. FIG. 19B illustrates a configuration of the semiconductor wafer 10 over which the first resin film 20 and the recesses 32 of the second resin film 30 have been formed. The resin film is formed by dispensing. A resin is applied onto the first main surface 11 of the semiconductor wafer 10 with the syringe 41 using two types of gas pressure to form the first resin film 20 and the second resin film 30 in one go. In this case, the dispensing mechanism 40 performs control so that the pressure, such as the gas pressures, decreases only at a timing of forming the recesses 32. The resin is herein applied to portions of the first main surface 11 with the syringe 41 using second gas pressure lower than first gas pressure when the first resin film 20 is formed. The first resin film 20 and the recesses 32 of the second resin film 30 are thereby formed in one go. The film thickness t2 of the second resin film 30 is similar to the film thickness t1 of the first resin film 20, and, as a specific range thereof, the film thickness t2 of the second resin film 30 is the same as or within 10% greater or smaller than the film thickness t1 of the first resin film 20.

In step S53, the semiconductor wafer 10 over which the first resin film 20 and the second resin film 30 have been formed is subjected to heating. After heating, the semiconductor wafer 10 is cooled to the room temperature. The cooling method is natural cooling, for example, and may be any other cooling means.

After steps S51 to S53, the subsequent step is performed. The method of manufacturing the semiconductor device according to Embodiment 10 is as described above.

A semiconductor device manufactured by the manufacturing method according to Embodiment 10 prevents the transfer error and breakage of the semiconductor wafer 10 in the subsequent step to improve yield. Furthermore, a processing time is reduced in the manufacturing method according to Embodiment 10 compared with that according to Embodiment 9 as the first resin film 20 and the second resin film 30 are formed in one go.

When the semiconductor device according to Embodiment 6 is manufactured, the recesses 32 of the second resin film 30 are formed along the U-shaped downward bowing due to the crystal plane orientation or the U-shaped downward bowing due to the device pattern film. A greater effect of reducing bowing is thereby obtained.

Embodiments of the present disclosure can freely be combined with each other and can be modified or omitted as appropriate.

Various aspects of the present disclosure will collectively be described below as appendices.

### Appendix 1

A protective film to protect a surface of a semiconductor wafer, the semiconductor wafer including a main surface and a device pattern film provided superficially in the main surface, the protective film comprising:
a first resin film covering the main surface of the semiconductor wafer; and
a second resin film having a film thickness that is the same as or within 10% greater or smaller than a film thickness of the first resin film and including a protrusion provided on a portion of a surface of the first resin film.

### Appendix 2

The protective film according to Appendix 1, wherein
the semiconductor wafer bows downward in a U shape in accordance with a crystal plane orientation of the main surface, and
the protrusion of the second resin film is provided along a direction of extension of a bottom of the U shape.

### Appendix 3

The protective film according to Appendix 1, wherein
the semiconductor wafer bows downward in a U shape in accordance with the device pattern film, and
the protrusion of the second resin film is provided along a direction of extension of a bottom of the U shape.

### Appendix 4

The protective film according to any one of Appendices 1 to 3, wherein
the second resin film is formed of the same material as the first resin film or a thermally expandable resin.

### Appendix 5

A semiconductor device comprising:
a semiconductor wafer including a main surface; and
a device pattern film provided superficially in the main surface of the semiconductor wafer, wherein
the device pattern film includes a conducting portion and a termination portion provided around the conducting portion, and
the semiconductor wafer has a greater thickness in the termination portion than in the conducting portion.

### Appendix 6

A protective film to protect a surface of a semiconductor wafer, the semiconductor wafer including a main surface and a device pattern film provided superficially in the main surface, the protective film comprising:
a first resin film covering the main surface of the semiconductor wafer; and
a second resin film having a film thickness that is the same as or within 10% greater or smaller than a film thickness of the first resin film and including a recess from which a portion of a surface of the first resin film is exposed.

### Appendix 7

The protective film according to Appendix 6, wherein
the semiconductor wafer bows downward in a U shape in accordance with a crystal plane orientation of the main surface, and
the recess of the second resin film is provided along a direction of extension of a bottom of the U shape.

### Appendix 8

The protective film according to Appendix 6, wherein
the semiconductor wafer bows downward in a U shape in accordance with the device pattern film, and
the recess of the second resin film is provided along a direction of extension of a bottom of the U shape.

### Appendix 9

A method of forming the protective film according to any one of Appendices 1 to 4, the method comprising:
preparing the semiconductor wafer including the main surface and the device pattern film provided superficially in the main surface;
forming the first resin film covering the main surface of the semiconductor wafer; and
forming the second resin film having the film thickness that is the same as or within 10% greater or smaller than the film thickness of the first resin film and including the protrusion provided on the portion of the surface of the first resin film, wherein
forming the first resin film includes
   applying a resin onto the main surface of the semiconductor wafer with a syringe using gas pressure to form the first resin film, and
forming the second resin film includes
   applying a resin onto a portion of the first resin film with the syringe using the gas pressure to form the protrusion of the second resin film.

### Appendix 10

A method of forming the protective film according to any one of Appendices 1 to 3, the method comprising:
preparing the semiconductor wafer including the main surface and the device pattern film provided superficially in the main surface; and
forming a resin film including the first resin film covering the main surface of the semiconductor wafer and the second resin film having the film thickness that is the same as or within 10% greater or smaller than the film thickness of the first resin film and including the protrusion provided on the portion of the surface of the first resin film, wherein
forming the resin film includes
   applying a resin onto the main surface of the semiconductor wafer with a syringe using first gas pressure and applying the resin to the main surface with the syringe using second gas pressure higher than the first gas pressure to form the first resin film and the protrusion of the second resin film in one go.

### Appendix 11

A method of forming the protective film according to any one of Appendices 6 to 8, the method comprising:
preparing the semiconductor wafer including the main surface and the device pattern film provided superficially in the main surface;
forming the first resin film covering the main surface of the semiconductor wafer; and
forming the second resin film having the film thickness that is the same as or within 10% greater or smaller than the film thickness of the first resin film and including the recess from which the portion of the surface of the first resin film is exposed, wherein
forming the first resin film includes
   applying a resin onto the main surface of the semiconductor wafer with a syringe using gas pressure to form the first resin film, and
forming the second resin film includes
   applying a resin onto a portion of the first resin film with the syringe using the gas pressure to form the recess of the second resin film.

### Appendix 12

A method of forming the protective film according to any one of Appendices 6 to 8, the method comprising:
preparing the semiconductor wafer including the main surface and the device pattern film provided superficially in the main surface;
forming a resin film including the first resin film covering the main surface of the semiconductor wafer and the second resin film having the film thickness that is the same as or within 10% greater or smaller than the film thickness of the first resin film and including the recess from which the portion of the surface of the first resin film is exposed, wherein
forming the resin film includes
   applying a resin onto the main surface of the semiconductor wafer with the syringe using first gas pressure and applying the resin to the main surface with the syringe using second gas pressure lower than the first gas pressure to form the first resin film and the recess of the second resin film in one go.

While the disclosure has been shown and described in detail, the foregoing description is in all aspects illustrative and not restrictive. It is therefore understood that numerous modifications and variations can be devised.

What is claimed is:

1. A protective film to protect a surface of a semiconductor wafer, the semiconductor wafer including a main surface and a device pattern film provided superficially in the main surface, the protective film comprising:
a first resin film covering the main surface of the semiconductor wafer; and
a second resin film having a film thickness that is the same as or within 10% greater or smaller than a film thickness of the first resin film and including a protrusion provided on a portion of a surface of the first resin film.

2. The protective film according to claim 1, wherein
the semiconductor wafer bows downward in a U shape in accordance with a crystal plane orientation of the main surface, and
the protrusion of the second resin film is provided along a direction of extension of a bottom of the U shape.

3. The protective film according to claim 1, wherein
the semiconductor wafer bows downward in a U shape in accordance with the device pattern film, and
the protrusion of the second resin film is provided along a direction of extension of a bottom of the U shape.

4. The protective film according to claim 1, wherein
the second resin film is formed of the same material as the first resin film or a thermally expandable resin.

5. A semiconductor device comprising:
a semiconductor wafer including a main surface; and
a device pattern film provided superficially in the main surface of the semiconductor wafer, wherein
the device pattern film includes a conducting portion and a termination portion provided around the conducting portion, and
the semiconductor wafer has a greater thickness in the termination portion than in the conducting portion.

6. A protective film to protect a surface of a semiconductor wafer, the semiconductor wafer including a main surface and a device pattern film provided superficially in the main surface, the protective film comprising:
a first resin film covering the main surface of the semiconductor wafer; and
a second resin film having a film thickness that is the same as or within 10% greater or smaller than a film thickness of the first resin film and including a recess from which a portion of a surface of the first resin film is exposed.

7. The protective film according to claim 6, wherein
the semiconductor wafer bows downward in a U shape in accordance with a crystal plane orientation of the main surface, and
the recess of the second resin film is provided along a direction of extension of a bottom of the U shape.

8. The protective film according to claim 6, wherein
the semiconductor wafer bows downward in a U shape in accordance with the device pattern film, and
the recess of the second resin film is provided along a direction of extension of a bottom of the U shape.

9. A method of forming the protective film according to claim 1, the method comprising:
preparing the semiconductor wafer including the main surface and the device pattern film provided superficially in the main surface;
forming the first resin film covering the main surface of the semiconductor wafer; and
forming the second resin film having the film thickness that is the same as or within 10% greater or smaller than the film thickness of the first resin film and including the protrusion provided on the portion of the surface of the first resin film, wherein
forming the first resin film includes
applying a resin onto the main surface of the semiconductor wafer with a syringe using gas pressure to form the first resin film, and
forming the second resin film includes
applying a resin onto a portion of the first resin film with the syringe using the gas pressure to form the protrusion of the second resin film.

10. A method of forming the protective film according to claim 1, the method comprising:
preparing the semiconductor wafer including the main surface and the device pattern film provided superficially in the main surface; and
forming a resin film including the first resin film covering the main surface of the semiconductor wafer and the second resin film having the film thickness that is the same as or within 10% greater or smaller than the film thickness of the first resin film and including the protrusion provided on the portion of the surface of the first resin film, wherein
forming the resin film includes
applying a resin onto the main surface of the semiconductor wafer with a syringe using first gas pressure and applying the resin to the main surface with the syringe using second gas pressure higher than the first gas pressure to form the first resin film and the protrusion of the second resin film in one go.

11. A method of forming the protective film according to claim 6, the method comprising:
preparing the semiconductor wafer including the main surface and the device pattern film provided superficially in the main surface;
forming the first resin film covering the main surface of the semiconductor wafer; and
forming the second resin film having the film thickness that is the same as or within 10% greater or smaller than the film thickness of the first resin film and including the recess from which the portion of the surface of the first resin film is exposed, wherein
forming the first resin film includes
applying a resin onto the main surface of the semiconductor wafer with a syringe using gas pressure to form the first resin film, and
forming the second resin film includes
applying a resin onto a portion of the first resin film with the syringe using the gas pressure to form the recess of the second resin film.

12. A method of forming the protective film according to claim 6, the method comprising:
preparing the semiconductor wafer including the main surface and the device pattern film provided superficially in the main surface;
forming a resin film including the first resin film covering the main surface of the semiconductor wafer and the second resin film having the film thickness that is the same as or within 10% greater or smaller than the film thickness of the first resin film and including the recess from which the portion of the surface of the first resin film is exposed, wherein
forming the resin film includes
applying a resin onto the main surface of the semiconductor wafer with the syringe using first gas pressure and applying the resin to the main surface with the syringe using second gas pressure lower than the first gas pressure to form the first resin film and the recess of the second resin film in one go.
